(19) United States
(12) Patent Application Publication
(10) Pub. No.: US 2025/0137928 A1
(43) Pub. Date: May 1, 2025

(54) METHOD FOR MONITORING EMBRITTLEMENT OF AN INTERFACE BETWEEN A SUBSTRATE AND LAYER AND A DEVICE ENABLING SUCH MONITORING

(71) Applicants: COMMISSARIAT A L'ENERGIE ATOMIQUE ET AUX ENERGIES ALTERNATIVES, Paris (FR); SOITEC, Bernin (FR)

(72) Inventors: Frédéric MAZEN, Grenoble Cedex 9 (FR); François RIEUTORD, Grenoble Cedex 9 (FR); Samuel TARDIF, Grenoble Cedex 9 (FR); Didier LANDRU, Bernin (FR); Oleg KONONCHUK, Bernin (FR); Nadia BEN MOHAMED, Bernin (FR)

(73) Assignees: COMMISSARIAT A L'ENERGIE ATOMIQUE ET AUX ENERGIES ALTERNATIVES, Paris (FR); SOITEC, Bernin (FR)

(21) Appl. No.: 18/837,719

(22) PCT Filed: Feb. 14, 2023
(86) PCT No.: PCT/FR2023/050192

§ 371 Date: Aug. 12, 2024

(30) Foreign Application Priority Data
Feb. 14, 2022 (FR) FR2201270

(51) Int. Cl. G01N 21/47; H01L 21/66; H01L 21/67

(52) U.S. Cl. CPC G01N 21/4738; H01L 21/67253; H01L 22/12; G01N 2201/121; G01N 2201/127

(57) ABSTRACT

A method and device for monitoring the weakening of an interface between a layer and a substrate while a weakening anneal is being carried out. The method includes illuminating the first face of the substrate layer assembly with a monochromatic light beam in a first direction; measuring the intensity of the light beam scattered by the substrate layer assembly in at least a second direction, the second direction forming a non-zero angle with the first direction; and determining a state of weakening of the interface from the intensity.

### TECHNICAL FIELD

The invention relates to the field of manufacturing structures in microelectronics and optoelectronics and in particular the field of transferring semiconductor layers able to be used in the context of such manufacture.

The object of the invention is thus more particularly a method for monitoring the weakening of an interface between a substrate and a layer, a method for weakening such an interface, a device enabling weakening of this same interface to be monitored and a system for fracturing an interface between a substrate and a layer.

### PRIOR ART

in the context of the manufacture of structures in microelectronics and/or optoelectronics, a semiconductor layer is often transferred from a donor substrate to a host substrate by a method of the Smart Cut™ type comprising a step of implantation in the donor substrate to create a buried fragile interface delimiting the semiconductor layer to be transferred.

Such a transfer requires, after glueing of the donor substrate/layer assembly on the host substrate by said layer, fracturing between the donor substrate and the layer to be transferred at the buried fragile interface. This fracturing is generally implemented by a weakening anneal allowing growth and coalescence of the micro-cavities formed at said interface.

FIG. 1 illustrates a variation in roughness along the layer after the fracturing. This variation in roughness is in particular the consequence of the differences in size of the cracks at the moment when the fracturing occurs at the scale of the wafer. It can have various sources and in particular the non-homogeneities of the implantation or of the weakening anneal or the variations in stresses in the stack.

Because of this, it would be advantageous to be able to monitor the weakening of the interface between the donor substrate and the layer to be transferred during the weakening anneal. Currently, such monitoring can be obtained by infrared microscopy. Though such imaging makes it possible to obtain an image of the micro-cavities and therefore to quantify the characteristics of the population and development thereof, it is not really adapted to in situ measurements in a fracturing oven, in particular when the latter is of the industrial type.

This is because, for such imaging, it is necessary to have a distance between lens and sample (i.e. the donor substrate/layer/host substrate assembly) that is small (a few millimetres at the very most), which particularly complicates its incorporation thereof in an industrial fracturing oven.

Moreover, at temperature, the IR radiation emitted by the plates and the oven may jam the IR signal used for viewing and therefore requires very powerful sources for illuminating the wafers.

### DESCRIPTION OF THE INVENTION

The invention aims to remedy the above drawback and thus the invention has the object of providing a method for monitoring weakness that is compatible with the constraints of a fracturing oven, in particular industrial, and which in particular does not require the installation of a lens at a short distance from the substrate/layer assembly the interface of which must be monitored and particularly powerful radiation sources.

The invention relates for this purpose to a method for monitoring weakening of an interface between a layer and a substrate during a weakening anneal of said interface, the substrate/layer assembly having at least a first and a second face, the method comprising the following steps:
illuminating the first face with a monochromatic light beam in a first direction,
measuring an intensity of the light beam scattered by the substrate/layer assembly in at least one second direction, the second direction having a non-zero angle with the first direction,
determining a state of weakening of the interface from said intensity.

The inventors identified that the intensity of the light scattered at a given angle with respect to the first direction was characteristic of the size of the micro-cavities and of the distance between same. Because of this, by monitoring the variation in this intensity during a weakening anneal, it is possible to monitor the weakening of the interface between the layer and the substrate. Such illumination and such measurement can be implemented at a distance from the substrate/layer assembly and the method therefore has the advantage of being perfectly compatible with the constraints relating to the fracturing oven, in particular of the industrial type. It should be noted in particular that the method according to the invention makes it possible to implement such monitoring from outside the enclosure of the fracturing oven, since the light source and the sensor can be arranged at a distance from the substrate/layer assembly and are compatible with the use of viewing windows.

It should be noted that the first direction corresponds to a direction of incidence of the monochromatic light beam while the second direction or directions correspond to one or more observation directions used for monitoring the fracturing. Thus, in the present document, it is perfectly possible to substitute “incident direction” for “first direction” and “observation direction” for “second direction” without changing the teaching thereof.

When the intensity of the light beam is measured, the intensity can be measured in a plurality of second directions each having a non-zero angle with the first direction and, preferentially, at least two of said second directions can have angles distinct from each other with respect to the first direction.

In this way, it is possible to obtain a more precise measurement, when these at least two directions have identical angles with respect to the first direction, and to be concerned with at least two second directions of interest corresponding to weakening states of interest, in the case where said at least two directions have angles distinct from each other with respect to the first direction.

This possibility allows to measure intensity in a range of second directions, as will be discussed in relation to FIGS. 3 to 5.

A prior calibration step can be provided, implemented before the weakening anneal, comprising the following substeps:
illuminating the first face with a light beam in the first direction,
measuring a reference intensity of the light beam scattered by the substrate/layer assembly in the at least one second direction,
wherein, during the step of determining a weakening state, a substep of correcting the intensity measured from the reference intensity is provided.

In this way, the scattering peak related to the cavities formed during weakening of the interface can easily be identified and it is therefore easy to determine the state of weakening of the interface.

During the illumination of the first face with the light beam in the first direction, the light beam can be moved in at least two regions, or zones, of the first face.

Thus it is possible to check the homogeneity of the weakening of the interface along the first face.

In a variant, of such a measurement at two locations by moving the light beam, provision can be made, to allow such measurement in at least two regions, for:
illuminating the first face by the light beam and another light beam, both in the first direction,
measuring the intensities of the light beam and of the other light beam scattered by the substrate/layer assembly in at least the second direction,
determining a state of weakening of the interface from said intensities at said at least two regions.

The monochromatic light beam can have a wavelength included in the infrared wavelength range, preferentially the near infrared, said wavelength being even more advantageously between 1050 nm and 1550 nm.

Such a wavelength is particularly adapted when the substrate and/or THE layer is/are produced from silicon, germanium, or a silicon germanium alloy.

It should be noted that, as an alternative, the light beam may have a wavelength in the visible range.

Such alternative is particularly adapted when the substrate and/or the layer is/are produced from a large-gap semiconductor such as gallium nitride, aluminium nitride, an alloy of the two, or a silicon carbide.

The invention furthermore relates to a method for weakening an interface between a layer and a substrate comprising a step of weakening anneal of the substrate/layer assembly in order to weaken said interface, in which, during said anneal step, a method for monitoring the weakening according to the invention is implemented.

Such a method benefits from the advantages related to the monitoring allowed by a monitoring method according to the invention. With such a method, it is thus easy to monitor the maturing of the cavities present at the interface and where applicable to retroact.

It is thus possible to adjust accordingly the conditions of the weakening anneal, in particular to obtain a required distribution of micro-cracks. It is possible for example to modify the heating profile of the oven in real time.

The weakening anneal step can be stopped when a state of weakening of the interface measured by the weakening monitoring method reaches a given threshold, the weakening state preferentially corresponding to a fracturing of the interface, said fracturing being detected then by a variation in intensity in the at least one second direction and/or a movement of the scattering peak.

In this manner, it is possible to optimise the fracturing, the anneal being able to be stopped at the most opportune moment.

It should be noted in particular that, according to one possibility of the invention, the state of weakening can be selected so as to implement fracturing outside the oven in which the weakening anneal is implemented. In this manner, if the weakening method so requires, it will be possible to implement the fracturing outside the oven.

The anneal conditions used during the anneal step can be modified according to the state of weakening of the interface determined during the implementation of the weakening-monitoring method.

In this manner, it is possible to optimise the weakening anneal, and in particular the heating profile of the oven, according to the state of weakening of the interface, in order to obtain a required distribution of micro-cracks at the interface.

The invention furthermore relates to a device for monitoring the weakening of the interface to monitor the weakening of an interface between a layer and a substrate during a weakening anneal of said interface, the substrate/layer assembly having at least one first and one second face, comprising:
an optical source able to emit a monochromatic light beam in the direction of the first face in a first direction,
an electromagnetic-radiation detector able to measure an intensity of the light beam after scattering by the substrate/layer assembly, the electromagnetic-radiation detector being arranged to measure said intensity of the light beam in a second direction having a non-zero angle with the first direction.

Such a device is adapted to implement a monitoring method according to the invention and therefore to benefit from the associated advantages.

The electromagnetic-radiation detector can be arranged to allow a measurement of the intensity of the light beam after scattering in a plurality of second directions each having a non-zero angle with the first direction and, preferentially, at least two of said second directions have angles distinct from each other with respect to the first direction.

In this manner, it is possible to obtain a more precise measurement, when these at least two directions have identical angles with respect to the first direction, and to be concerned with at least two second directions of interest corresponding to weakening states of interest, in the case where said at least two directions have angles distinct from each other with respect to the first direction.

It should be noted that such an arrangement of the electromagnetic-radiation detector can be provided by using at least two electromagnetic-radiation detection units each arranged to detect the intensity of the light beam after scattering in a respective second direction.

The detector can thus for example take the form of a matrix of such units (or pixels) in order to allow measurement in a plurality of second directions.

It should be noted that each of these units can be provided with one optical component to allow measurement of the intensity of the light beam after scattering in the corresponding second direction.

The weakening-monitoring device can further comprise a processing unit configured to recover an intensity value of the light beam measured by the detector and to determine a state of weakening of the interface from said intensity value of the light beam.

Such a processing unit facilitates the use of the monitoring device according to the invention, the technician implementing the weakening anneal having direct access to a state of weakening of the interface.

The processing unit can furthermore be configured to, when the state of weakening of the interface is determined, correct the measured intensity based on a reference intensity determined before the weakening anneal.

In this manner, the scattering peak related to the cavities formed during weakening of the interface can easily be identified.

The invention furthermore relates to an annealing oven 40 able to implement a weakening anneal in order to weaken an interface between a layer and a substrate, the oven comprising a weakening-monitoring device according to the invention.

With such a weakening-monitoring device, such an annealing oven allows in situ weakening monitoring that is perfectly adapted to annealing ovens of the industrial type.

The annealing oven can comprise a first location for the substrate/layer assembly and at least one second location for another substrate/layer assembly in order to allow a simultaneous weakening anneal of the substrate/layer assembly and of the other substrate/layer assembly,
the second location being arranged so that a face of the other substrate/layer assembly is illuminated by the light beam after the light beam has passed through the substrate/layer assembly,
and the electromagnetic-radiation detector furthermore being able to measure an intensity of the light beam after scattering by the other substrate/layer assembly, the electromagnetic-radiation detector being arranged to measure said intensity of the light beam in another second direction having a non-zero angle with the first direction.

With such an annealing oven, it is possible to implement an interface weakening anneal for a plurality of substrate/layer assemblies while monitoring the weakening of at least two of said interfaces, or even of all of said interfaces.

It should be noted that, in such a configuration, the electromagnetic-radiation detector can comprise at least two detection units, each dedicated to a corresponding location from the first and second locations.

The annealing oven can be configured so that, when a weakening anneal is implemented, an anneal of the substrate/layer assembly is stopped when the weakening-monitoring device determines that the state of weakening of the interface measured reaches a given threshold.

In this manner, it is possible to provide an optimised weakening anneal since it is based on a monitoring of the weakening of the interface.

The annealing oven can comprise a control unit configured to communicate with a processing unit of the weakening-monitoring device and to adjust the conditions of the weakening anneal according to the state of weakening supplied by the weakening-monitoring device.

### BRIEF DESCRIPTION OF THE DRAWINGS

The present invention will be understood better from the reading of the description of example embodiments given only by way of indication and in no way limitatively, referring to the accompanying drawings, on which:

FIG. 1 illustrates a roughness mapping implemented on a semiconductor layer after fracturing of its interface with a donor substrate from which said semiconductor layer came, a light value corresponding to maximum roughness;

FIG. 2 illustrates a weakening oven equipped with a weakening-monitoring device according to the invention;

FIG. 3 illustrates graphically the variations in intensity of the beam scattered by a layer/substrate assembly as a function of the scattering angle obtained from the weakening-monitoring device according to the invention measured respectively before and during weakening anneal;

FIG. 4 illustrates graphically the intensity variation differential as a function of the scattering angle calculated by subtracting from the intensity measured during weakening anneal the intensity measured before the weakening anneal;

FIG. 5 compares graphically the intensity of the scattered beam measured using a device according to the invention with a Fourier transform of a confocal microscopy image as implemented in the prior art.

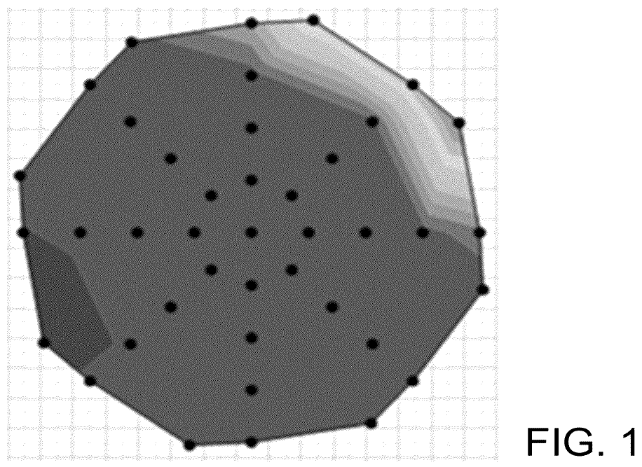

Identical, similar or equivalent parts of the various figures bear the same numerical references so as to facilitate passing from one figure to another.

The various parts shown on the figures are not necessarily shown to a uniform scale, to make the figures more legible.

The various possibilities (variants and embodiments) must be understood as not being exclusive of each other and can be combined with each other.

### DETAILED DESCRIPTION OF PARTICULAR EMBODIMENTS

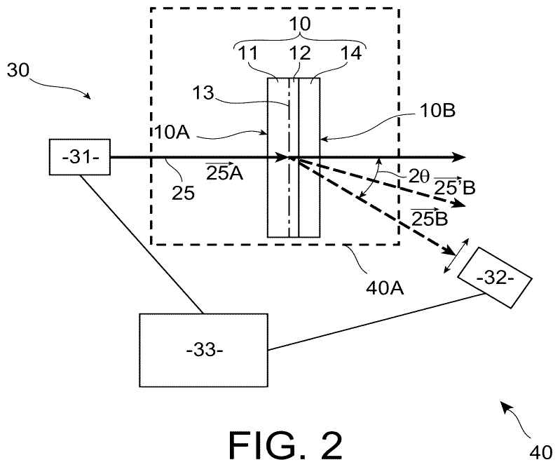

FIG. 2 illustrates a weakening oven 40 in which a weakening anneal of an interface 13 between a donor substrate 11 and a layer 12 is implemented, said weakening oven 40 being equipped with a weakening-monitoring device 30 according to the invention in order to allow monitoring of the weakening of said interface 13.

It should be noted that, in a normal configuration of the invention, as illustrated on FIG. 2, the elements of the weakening-monitoring device 30 are arranged outside the enclosure 40A of the weakening oven 40, the enclosure 40A then being equipped with viewing windows, not illustrated, to allow weakening monitoring by the weakening-monitoring device 30 according to the invention. Such a normal configuration is in no way limitative and it can perfectly be envisaged, without departing from the scope of the invention, that at least some of the elements of the weakening-monitoring device 30 are at least partly arranged in the enclosure 40A of the weakening oven 40.

In the context of the present example embodiment, the substrate, referred to as the donor substrate, and the layer that is to be transferred are respectively a substrate and a layer of monocrystalline silicon Si. Because of this, the wavelengths, values and other measurements indicated below and in the rest of this document are adapted for such a material. Naturally, from such a teaching, a person skilled in the art is in a position to adapt the present teaching to other types of material. Thus the invention is also particularly adapted in the context of a weakening of an interface between a layer and a substrate, both produced from germanium Ge, in a silicon-germanium Si—Ge alloy or in a silicon carbide SiC, or even for a silicon Si substrate and a layer of silicon carbide SiC.

Naturally, if in the invention concerns the monitoring of the weakening of an interface 13 between a substrate 11 and the layer 12 that it supports, in a conventional application of the invention, the weakening anneal follows a step of gluing said layer to a host substrate 14, the substrate 11 being the donor substrate used in the context of transferring the layer 12 to the host substrate 14. Thus, if in the general context of the invention the substrate 11/layer 12 assembly 10 comprises the substrate 11 and the layer 12, in the conventional application of the invention, the assembly 10 also comprises the host substrate as is shown on FIG. 2.

Such a weakening-monitoring device 30 comprises:
an optical source 31 able to emit a monochromatic light beam 25 in the direction of the first face 10A, the wavelength of said light beam 25 being selected so that the layer 12 and the substrates 11 of 14 are substantially transparent to said wavelength,
an electromagnetic-radiation detector 32 able to measure an intensity of the light beam 25 after scattering by the substrate 11/layer 12 assembly 10, the electromagnetic-radiation detector being arranged to measure said intensity of the light beam 25 in a second direction having a non-zero angle 20 with the first direction 25A.

Naturally, such a second direction 25B of detection of a light beam 25 scattered by the substrate 11/layer 12 assembly 10 crosses the first direction 25A, along which the light beam 25 is emitted, at the level of the scattering element at the origin of said scattering, i.e. the substrate 11/layer 12 assembly 10 (or more precisely the interface 13 between the layer 11 and the substrate 12).

In a normal scattering configuration, the second direction 25B can, as illustrated on FIG. 2, extend from the second face of the support while moving away from the latter. In a variant, not illustrated, in which the scattering measured by the detector is a backscattering, the second direction 25B can extend from the first face while moving away from the latter. Such a possibility is particularly advantageous in order to allow observation of the scattering with an opaque host/receiver substrate or when the transmission angles are not accessible.

It should thus be noted that, by scattering of the light beam by the substrate 11/layer 12 assembly 10, both a scattering as such, i.e. the light beam is scattered from the interface 13 in the direction of the second face 10B, and a backscattering, i.e. the light beam is scattered from the interface 13 in the direction of the first face 10B, must be understood here and in the rest of this document.

As described below, a processing unit 33 able to control the optical source and the electromagnetic-radiation detector 32 in order to calibrate a state of weakening of the interface 13 based on the intensity measured by the electromagnetic-radiation detector 32, can furthermore be provided.

The optical source 31 is a light source able to provide/emit the light beam 25 with a wavelength adapted to the transparency of the material or materials of the substrate 11 and of the layer 12. In the case of the present example embodiment, i.e. a silicon layer and substrate, the wavelength of the light beam can be a wavelength in the infrared, preferably near infrared. Thus the light beam 25 can have a wavelength of between 1050 nm and 1550 nm, and be for example equal to 1.2 μm, to 1.5 μm, or 1.3 μm. To allow such provision, the optical source can be a laser source, such as a semiconductor laser, laser diode; or a light-emitting diode. Preferentially the optical source 31 can comprise a system for guiding the light beam 25, such as an optical fibre, advantageously comprising a collimation system (lenses, mirrors) to define the size and divergence of the light beam after emission thereof.

As illustrated on FIG. 2, the first direction 25A is preferentially perpendicular to the first surface. Naturally other first directions 25A can be envisaged without departing from the scope of the invention.

The electromagnetic-radiation detector 32 is configured to receive electromagnetic radiation in a range of wavelengths including the wavelength of the light beam 25 emitted by the optical source 31 and to provide a signal representative of the intensity of the radiation received. Thus the electromagnetic-radiation detector can include a photodetector such as a photodiode or a plurality of photodiodes organised in a matrix. Thus, for example, the electromagnetic-radiation detector 32 can include a CMOS or CCD sensor the spectral response of which is adapted to the source used. In such a configuration, the various photodiodes or pixels form detection units.

The electromagnetic-radiation detector 32 can comprise, apart from such a photodetector, a lens in order to concentrate the part of the light beam 25 scattered in the second direction 25B onto said photodetector.

According to a first possibility of the invention, the electromagnetic-radiation detector can be arranged to receive the part of the beam scattered in a predetermined second direction 25B and to selectively image the light-emitting zone. According to this possibility, the second direction is selected to correspond to a direction of interest, i.e. having an angle of interest 20 with respect to the first direction 25A, corresponding to a predetermined state of weakening of the interface 13.

It should be noted that, in the case where the electromagnetic-radiation detector 32 comprises a plurality of detection units, the radiation detector can comprise a plurality of optical systems each dedicated to one or to a group of respective detection units. Said optical systems each being arranged to allow a measurement of intensity of the light beam 25 scattered by the substrate 11/layer 12 assembly 10 in a second direction 25B that is respective to it.

In conformity with the present example embodiment, the inventors identified that, in the context of such a possibility, a second direction having an angle 20 of between 5 and 15°, preferentially between 8 and 12° and substantially equal to 10°, corresponded to a state of weakening of the interface 13 adapted to provide optimised fracturing. The inventors indeed identified that such an angle value of 10° of the second direction 25B with respect to the first direction 25A corresponds to micro-cracks of 10 μm and to a maturity of the weakening of interface 13 adapted to its fracturing.

According to a second possibility of the invention, the electromagnetic-radiation detector and its optical component can be arranged to receive a part of the beam scattered in a plurality of second directions 25B, 25B′ each having a non-zero angle 20 with the first direction. In this manner, it is possible to precisely monitor the state of weakening of the interface. This plurality of second directions can correspond to an angle range 20 with the first direction corresponding to several states of weakening of the interface 13 of interest (thus including for example 10° as mentioned above in the context of the first possibility).

According to a third possibility of the invention, the electromagnetic-radiation detector 32 can be arranged movable so as to allow a measurement of intensity of the beam after scattered thereof in a plurality of second directions 25B, 25B′ each having a non-zero angle 20 with the first direction. In the same way as for the second possibility disclosed above, this plurality of second directions can correspond to a range of angles 20 with the first direction corresponding to several weakening states of the interface 13 of interest (thus including for example 10° as mentioned above in the context of the first possibility).

It should also be noted, according to another possibility, compatible with the above three possibilities, that the weakening-monitoring device 30 can be configured to move the light beam 25 in at least two locations, or regions, of the first face 10A, the detector then being arranged to allow measurement of the intensity of the light beam 25 scattered by the substrate 11/layer 12 assembly 10 in the at least one second direction 25B for said at least two regions. Such a possibility allows mapping of the weakening state of the interface 13 along the first face 10A. Such a movement of the light beam 25 can be obtained by an adapted configuration of the optical source 31, this being either arranged movable or comprising an optical component, such as an optical fibre and/or a lens, movable in order to allow a movement of the light beam 25. Likewise the electromagnetic-radiation detector 31 is adapted to allow either by having an adapted arrangement for measuring the intensity in the at least one second direction 25B for all the measurement locations of the first face 10A, or by being movable to allow a measurement for each of these locations.

It should be noted that, in the present embodiment, though the weakening oven 40 accommodates a single substrate/layer assembly, it can perfectly well be envisaged that the weakening of oven 40 be adapted to allow a weakening anneal of a number of assemblies greater than or equal to two.

According to this possibility, not illustrated, the weakening oven 40 can include a first location for the substrate 11/layer 12 assembly and one or more second locations for one or more other substrate/layer assemblies in order to allow a simultaneous weakening anneal of the substrate 11/layer 12 assembly and of the other substrate/layer assembly or assemblies.

According to this same possibility, said second location or locations are arranged so that a face of the other substrate/layer assembly or assemblies is illuminated by the light beam after the latter has passed through the substrate 11/layer 12 assembly. The electromagnetic-radiation detector 32 is furthermore able to measure an intensity of the light beam 25 after scattering by the other substrate/layer assembly or assemblies, the electromagnetic-radiation detector 32 being arranged to measure said intensity of the light beam 25 in another second direction having a non-zero angle 20 with the first direction 25A. Such an arrangement can in particular be obtained by means of an electromagnetic-radiation detector 32 comprising, for each location, at least one respective unit and one respective optical system dedicated to said unit.

Naturally, in a variant, the weakening-monitoring device 30 can include one or more other electromagnetic-radiation detectors 32 in order to measure an intensity of the light beam 25 for one or more of the other substrate/layer assemblies.

The weakening-monitoring device 30 can further include a processing unit 33 configured to recover an intensity value of the light beam measured by the detector and to determine a weakening state of the interface from said intensity value of the light beam.

This same processing unit can furthermore be configured to, during the determination of the weakening state of the interface, correct the intensity measured based on a reference intensity determined before the weakening anneal.

Likewise, according to the possibility implemented among the various possibilities described above, the processing unit is able to determine the weakening state of the interface 13 from the values of the intensities measured in the plurality of second directions 25B, 25B′ and in various locations of the first face 10A. To do this, when the optical source 31 is configured to allow a movement of the light beam 25, and/or when the electromagnetic-radiation detector 32 is configured to measure the intensity in a plurality of second directions, control the optical source 31 and/or the electromagnetic-radiation detector 32 in conformity with the said possibility or possibilities.

It should be noted that, according to one possibility of the invention, the processing unit can be configured to supply to the weakening oven 40 the weakening state of the interface 13 determined. According to this possibility, the weakening oven 40 can be configured to stop the weakening anneal when the weakening state of the interface 13 determined by the processing unit 33 reaches a given threshold.

According to a variant of this possibility of the invention, the processing unit can furthermore be configured to detect the spontaneous fracturing of the assemblies at the end of annealing. Indeed this event is associated with an abrupt variation in intensity and of the position of the scattering intensity, which can be detected by the weakening-monitoring device 30 according to the invention. Thus, according to this variant, the given threshold of the weakening state corresponds to a fracturing of the interface 13, said fracturing being detected by an abrupt variation in intensity in the at least one second direction 25B and/or a movement of the scattering peak. In an identical manner the oven can comprise a control unit configured to communicate with the processing unit of the weakening-monitoring device and to adjust the weakening-anneal conditions according to the weakening state supplied by the weakening-monitoring device.

According to this last possibility, it is therefore possible to adjust the anneal conditions used during the anneal step according to the weakening state of the interface 13 determined during the implementation of the weakening-monitoring method. Thus it is possible to optimise the weakening anneal and in particular the heating profile of the oven, according to the weakening state of the interface, in order to obtain a required distribution of micro-cracks at the interface. This is particularly advantageous when it is sought to obtain fracturing outside the oven.

The weakening-monitoring device 30 according to the invention is able to allow the implementation of a weakening-monitoring method 30 comprising the following steps:
illuminating the first face 10A with the monochromatic light beam 25 in the first direction 25A, the wavelength of the light beam 25 being selected so that the layer 12 and the substrate 13 are substantially transparent to said wavelength,
measuring the intensity of the light beam 25 scattered by the substrate 11/layer 12 assembly 10 in the at least one second direction 25B, the second direction 25B having a non-zero angle 20 with the first direction 25A,
determining a weakening state of the interface 13 from said intensity.

Naturally, in conformity with the possibilities described in relation to the weakening-monitoring device 30, the method is compatible with these various possibilities. In particular, the method according to the invention can also comprise a prior calibration step implemented before the weakening anneal comprising the following substeps:
illuminating the first face with the monochromatic light beam 25 in the first direction 25A,
measuring a reference intensity of the light beam 25 scattered by the substrate 11/layer 12 assembly 10 in the at least one second direction 25B. During the step of determining a weakening state a substep of correcting the intensity measured from the reference intensity is then provided.

If such a weakening-monitoring device 30 and the corresponding method can be used in production in the context of a monitoring of a step of fracturing an interface 13 between a layer and a support, it can also be used in more specific cases such as during the calibration of a weakening oven 40 in the context of installation or overhaul of said oven. In this context the weakening-monitoring device 30 is not necessarily incorporated in said weakening oven 40 and can be installed removably in order to implement the calibration step. The weakening-monitoring device 30 can thus perfectly well be removed after implementation of said calibration step.

As indicated, in a normal configuration, the whole of the weakening-monitoring device 30 can be installed outside the enclosure 40A of the weakening oven 40, said enclosure 40A then being provided with viewing windows transparent to the incident light 25A and scattered light 25B.

### Examples of Implementations of the Invention

In order to illustrate the principle of implementation by the monitoring method according to the invention and to provide an example of determination of the weakening state of an interface, an example of measurements obtained by the inventors in the context of such an implementation is described below.

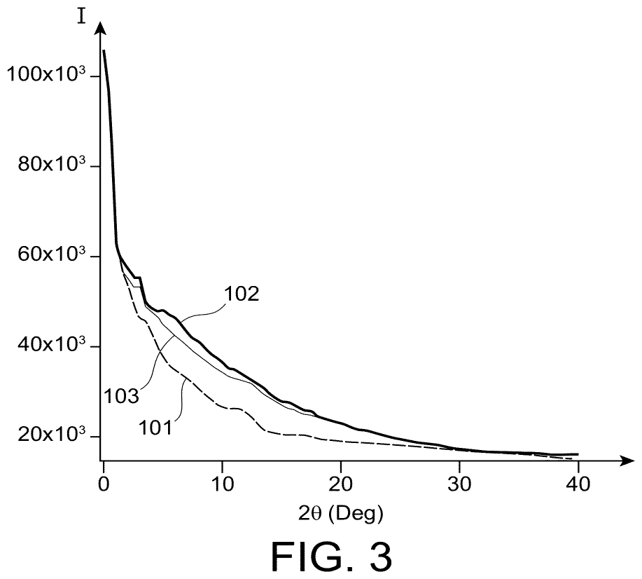

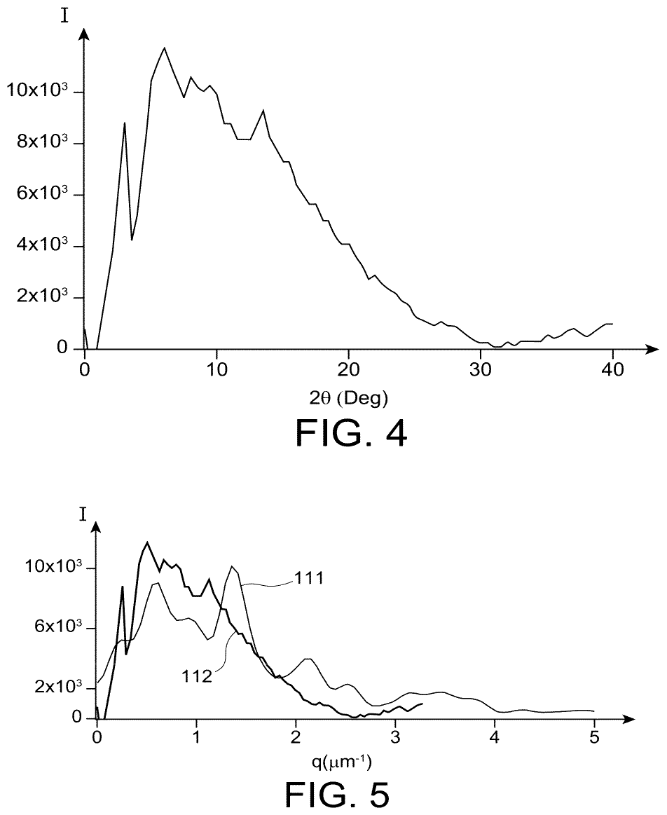

Thus, as illustrated on FIG. 3, in the context of implementation of such a method, the inventors measured the variation in intensity 102, 103 of the light beam 25 scattered as a function of the angle 20 between the second direction 25B and the first direction 25A, during a weakening anneal of a layer 12 of silicon supported by a silicon substrate 11 two different samples, the interface 13 between said layer and said substrate having been implanted previously to form micro-cavities at said interface 13. By way of comparison the inventors have shown on this same figure the variation in intensity 101 of the scattered light beam 25 as a function of the angle θ between the second direction 25B and the first direction 25A obtained on a substrate 11/layer 12 assembly 10 before weakening anneal, such a measurement being able to form, as discussed below in relation to FIG. 4, a reference measurement.

It can thus be seen that the coalescence of the micro-cavities and the increase in the size thereof because of this coalescence and at the origin of a significant increase in the scattered light over an angular range 20 from 1° to 12°. Thus, as the inventors discovered, the scattered light is characteristic of the size and distribution of the cavities at the interface 13 (such a characteristic being able to be formalised on the basis of a Fraunhofer approximation).

In order better to illustrate this phenomenon, the inventors have shown on FIG. 4 the variation in the difference between the intensity of the measured light beam 102 during weakening anneal and that measured 101 before anneal as a function of the angle 20 between the second direction 25B and the first direction 25A. It can be seen that the scattered light intensity related to the weakening anneal is maximum at around 9°, i.e. a micro-cavity size of approximately 8 microns.

By way of comparison, the inventors used a confocal microscope to obtain an infrared image of this same interface 13 that was characterised by the weakening-monitoring device during weakening anneal. The inventors effected a Fourier transform of this image and radially averaged the image thus obtained.

FIG. 5 graphically compares the result of this Fourier transform 111 with the variation in intensity as a function of twice the angle between the second direction 25B and the first direction 25A. This comparison shows that these two techniques make it possible to obtain similar results and therefore both make it possible to characterise the weakening state of the interface 13. The method according to the invention has, with respect to such confocal imagery, the advantage of not requiring placing a lens in proximity to the sample and therefore being perfectly able to equip a large industrial weakening oven.

It should be noted that, in the context of the invention, the weakening state of the surface determined using the method according to the invention can, for example, be supplied in the form of one of the following values:
the angle of the second direction 25B with respect to the first direction for which the increase in scattering intensity is maximum with respect to a reference intensity determined before the weakening anneal,
a micro-cavity size value estimated from the intensity of the light beam 25 scattered in the second direction or directions 25B, 25B′,
an intensity value of the light beam 25 scattered in a second reference direction 25B or a plurality of reference directions 25B, 25B′.

1. A method for monitoring weakening of an interface between a layer and a substrate during weakening anneal of said interface, an assembly of the substrate and layer having at least a first and a second face, comprising:
illuminating the first face with a monochromatic light beam in a first direction, a wavelength of the light beam being selected so that the layer and the substrate are substantially transparent to the wavelength,
measuring an intensity of the light beam scattered by the assembly in at least one second direction, the second direction having a non-zero angle with the first direction, and the second direction extending from the second face of the assembly while moving away from the assembly, and
determining a state of weakening of the interface from the intensity.

2. The weakening-monitoring method according to claim 1, wherein, during measurement of the intensity of the light beam, the intensity is measured in a plurality of second directions each having a non-zero angle with the first direction, and wherein at least two of the second directions have angles distinct from each other with respect to the first direction.

3. The weakening-monitoring method according to claim 1, wherein a prior calibration step is provided, implemented before the weakening anneal, comprising:
illuminating the first face with the light beam in the first direction, and
measuring a reference intensity of the light beam scattered by the assembly in the at least one second direction,
wherein, determining the weakening state comprises correcting the intensity measured based on a reference intensity.

4. The weakening-monitoring method according to claim 1, wherein, during illumination of the first face with the light beam in the first direction, the light beam is moved in at least two regions of the first face.

5. The weakening-monitoring method according to claim 1, wherein the monochromatic light beam has a wavelength lying in a range of infrared wavelengths.

6. A method for weakening an interface between a layer and a substrate, comprising a step of weakening anneal of an assembly of the substrate and the layer in order to weaken the interface, wherein, during the anneal step, a weakening-monitoring method according to claim 1 is implemented.

7. The method for weakening an interface according to claim 6, wherein the weakening-anneal step is stopped when a state of weakening of the interface determined by the weakening-monitoring method reaches a given threshold.

8. The method for weakening an interface according to claim 6, wherein anneal conditions used during the annealing are modified according to a state of weakening of the interface determined during the implementation of the weakening-monitoring method.

9. A device for monitoring weakening of an interface between a layer and a substrate during a weakening anneal of the interface, an assembly of the substrate and layer having at least one first and one second face, comprising:
an optical source configured to emit a monochromatic light beam in a direction of the first face in a first direction, and
an electromagnetic-radiation detector configured to measure an intensity of the light beam after scattering by assembly, the electromagnetic-radiation detector being arranged to measure the intensity of the light beam in a second direction having a non-zero angle with the first direction, and the second direction extending from the second face of the assembly while moving away from the assembly.

10. The weakening-monitoring device according to claim 9, wherein the electromagnetic-radiation detector is arranged to allow a measurement of the intensity of the light beam after scattering in a plurality of second directions each having a non-zero angle with the first direction.

11. The weakening-monitoring device according to claim 9, further comprising a processing unit configured to recover an intensity value of the light beam measured by the detector and to determine a weakening state of the interface based on the intensity value of the light beam.

12. The weakening-monitoring device according to claim 11, wherein the processing unit is further configured to, during the determination of the weakening state of the interface, correct the measured intensity based upon a reference intensity determined before the weakening anneal.

13. An annealing oven able to implement a weakening anneal in order to weaken an interface between a layer and a substrate, the annealing oven comprising the weakening-monitoring device according to claim 9.

14. The annealing oven according to claim 13, comprising a first location for the assembly and at least one second location for another substrate/layer assembly in order to allow a simultaneous weakening anneal of the assembly and of the other assembly,
wherein the second location is arranged so that a face of the other assembly is illuminated by the light beam after the light beam has passed through the assembly, and
wherein the electromagnetic-radiation detector is further configured to measure an intensity of the light beam after scattering by the other assembly, the electromagnetic-radiation detector being arranged to measure the intensity of the light beam in another second direction having a non-zero angle with the first direction.

15. The annealing oven according to claim 13, configured so that, when a weakening anneal is implemented, an anneal of the assembly is stopped when the weakening-monitoring device determines that the weakening state of the interface measured reaches a given threshold.

16. The weakening-monitoring method according to claim 1, wherein the monochromatic light beam has a wavelength lying in a range between 1050 nm and 1550 nm.

17. The method for weakening an interface according to claim 6, wherein the weakening-anneal step is stopped when a state of weakening of the interface corresponds to a fracturing of the interface, the fracturing being detected by a variation in intensity in the at least one second direction and/or a movement of a scattering peak.

18. The weakening-monitoring device according to claim 10, wherein at least two of the second directions have angles distinct from each other with respect to the first direction.
